(19) United States
(12) Patent Application Publication
(10) Pub. No.: US 2026/0255931 A1
(43) Pub. Date: Aug. 27, 2026

(54) CARRIER STRUCTURE

(71) Applicant: SILICONWARE PRECISION INDUSTRIES CO., LTD., Taichung City (TW)

(72) Inventors: Chia-Cheng CHEN, Taichung City (TW); Yueh-Chiung CHANG, Taichung City (TW); Hsiu-Fang CHIEN, Taichung City (TW)

(73) Assignee: SILICONWARE PRECISION INDUSTRIES CO., LTD., Taichung City (TW)

(21) Appl. No.: 19/261,871

(22) Filed: Jul. 7, 2025

(30) Foreign Application Priority Data
Feb. 24, 2025 (TW) 114106732

(51) Int. Cl. H01L 21/66; H01L 23/498

(52) U.S. Cl. CPC H10P 74/273; H10W 70/65; H10W 70/66

(57) ABSTRACT

A carrier structure is defined with a main area and a peripheral area adjacent to the main area, including a plurality of substrate units arranged in the main area, and a plurality of electrical connection pads provided on each substrate unit and at least two inspection pads arranged in the peripheral area. Whether the surface treatment layer formed on the electrical connection pads reaches the target thickness can be determined by directly observing the mutual contact status of the surface treatment layer formed on the two inspection pads when the surface treatment layer is formed on the electrical connection pads and the inspection pads.

### BACKGROUND

### 1. Technical Field

The present disclosure relates to a semiconductor structure, and more particularly, to a carrier structure for carrying semiconductor chips.

### 2. Description of Related Art

In the current structure where a packaging substrate or a lead frame electrically connects to a semiconductor chip via bonding wires and carries the semiconductor chip, electronic pads are formed on the surface of the semiconductor chip, and the packaging substrate has corresponding bonding pads, or the lead frame has corresponding leads. After the semiconductor chip is placed on the die mounting area of the packaging substrate or the die mounting base of the lead frame, the electronic pads of the semiconductor chip are electrically connected to the bonding pads of the packaging substrate or the leads of the lead frame using bonding wires (typically gold wires), such that the semiconductor chip is electrically connected to the packaging substrate or the lead frame.

At the same time, during the packaging process where the packaging substrate functions as a chip carrier, a nickel/gold layer is commonly electroplated on the bonding pads of the packaging substrate prior to the wire bonding operation, so as to improve the electrical coupling bonding force between the gold wires and the bonding pads and to prevent oxidation of the bonding pads.

However, if the thickness of the electroplated nickel/gold layer on the bonding pads is insufficient, it would cause problems such as abnormal wire bonding production line operations or insufficient resistance to external oxidation of the bonding pads. Hence, the current practice involves random sampling and destructive test (e.g., cross-section analysis) of the packaging substrate to ascertain whether the thickness of the nickel/gold layer meets the requirements. Nonetheless, this inspection approach not only complicates inspection but also results in wasted manpower, material resources, and working hours.

Therefore, how to overcome the above-mentioned drawbacks of the prior art has become an urgent issue to be solved at present.

### SUMMARY

In view of the aforementioned shortcomings of the prior art, the present disclosure provides a carrier structure, which is defined with a main area and a peripheral area adjacent to the main area, the carrier structure including: a plurality of substrate units disposed in the main area, and a plurality of electrical connection pads formed on each of the plurality of substrate units; and at least two inspection pads disposed in the peripheral area, wherein a distance between the at least two inspection pads is less than a distance between any two of the plurality of electrical connection pads.

In the aforementioned carrier structure, a surface treatment layer is formed on the plurality of electrical connection pads and the at least two inspection pads. In an embodiment, the surface treatment layer is a nickel/gold layer.

In an embodiment, the carrier structure is in a full-panel or a strip form, and the plurality of substrate units are arranged in an array.

In the aforementioned carrier structure, the substrate unit provides for an electronic component to be disposed thereon and for the electronic component to be electrically connected to the plurality of electrical connection pads.

In the carrier structure, a cutting path for a singulation process is provided between each of the substrate units.

In the carrier structure, the peripheral area is connected to the main area and is positioned outside the main area.

In the carrier structure, the inspection pads are made of the same material as the electrical connection pads.

In the carrier structure, a plurality of sets of inspection pads are disposed in the peripheral area, each set of inspection pads comprises two of the inspection pads, and a distance between two of the inspection pads in each set is equal, or a distance between two of the inspection pads in each set is different.

As can be seen from the above, the carrier structure of the present disclosure is mainly provided with at least two inspection pads in the peripheral area, and the distance between the two inspection pads is less than the distance between the two electrical connection pads disposed in the main area. As such, when a surface treatment layer is formed on the electrical connection pads and the inspection pads, whether the surface treatment layer formed on the electrical connection pads has reached the target thickness can be directly determined by direct vision or microscopic observation of the mutual distance and contact status of the surface treatment layer formed on the two inspection pads, without the need for destructive text.

### BRIEF DESCRIPTION OF THE DRAWINGS

FIG. 1 is a top plan schematic view showing a carrier structure according to the present disclosure.

FIG. 2A is a partially enlarged schematic top view and cross-sectional view showing a first aspect of the electrical connection pads of a carrier structure according to the present disclosure.

FIG. 2B is a partially enlarged schematic top view and cross-sectional view showing a first aspect of the inspection pads of a carrier structure according to the present disclosure.

FIG. 3A is a partially enlarged schematic top view and cross-sectional view showing a second aspect of the electrical connection pads of a carrier structure according to the present disclosure.

FIG. 3B is a partially enlarged schematic top view and cross-sectional view showing a second aspect of the inspection pads of a carrier structure according to the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “a,” “one” and the like are merely used for clear explanation rather than limiting the practicable scope of the present disclosure, and thus, alterations or adjustments of the relative relationships thereof without essentially altering the technical contents should still be considered in the practicable scope of the present disclosure.

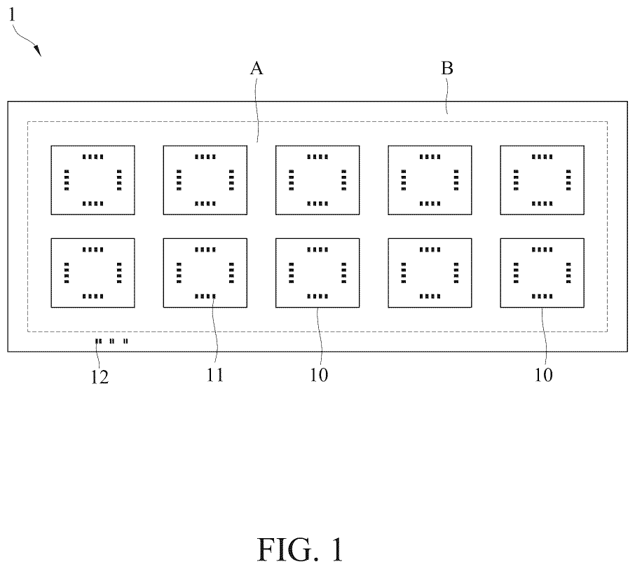

FIG. 1 is a top plan schematic view showing a carrier structure according to the present disclosure. As shown in FIG. 1, the carrier structure 1 is defined with a main area A and a peripheral area B adjacent to the main area A (their junction is the dotted line shown in FIG. 1). The carrier structure 1 includes: a plurality of substrate units 10 disposed in the main area A and inspection pads 12 disposed in the peripheral area B.

In one embodiment, the carrier structurer 1 is in a full-panel (also can be in a strip form such as strips), and the plurality of substrate units 10 are arranged in an array.

The substrate unit 10 is a circuit structure with a core layer or a coreless circuit structure, which has a dielectric layer and a circuit layer bonded to the dielectric layer. In one embodiment, the dielectric layer is made of polybenzoxazole (PBO), polyimide (PI), prepreg (PP), or other dielectric materials. The circuit layer is made of copper, and, for example, is manufactured by a redistribution layer (RDL) process.

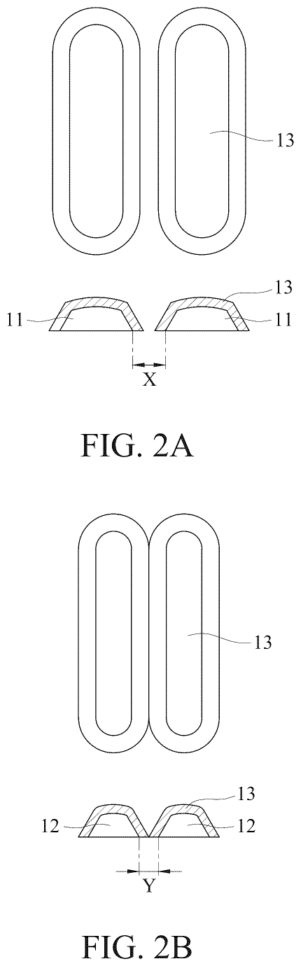

Referring to FIG. 2A, the circuit layer includes a plurality of electrical connection pads 11 forming the surface of the substrate unit 10, wherein the distance between two adjacent electrical connection pads 11 is X for subsequent connection to an electronic component on each of the substrate unit 10, such that the electronic component is electrically connected to the plurality of electrical connection pads 11. Electronic components are arranged on each of the substrate units 10 according to the required quantity, which may be active component, passive component, or a combination thereof, wherein the active component is, for example, a semiconductor chip, and the passive component is, for example, a resistor, a capacitor, and an inductor. In one embodiment, the electronic component is a semiconductor chip, which can be electrically connected to the electrical connection pads 11 of the substrate unit 10 by wire bonding (via gold wires).

Moreover, the main area A has a cutting path for a singulation process between each of the substrate units 10. The structure of the main area A can be manufactured according to the process and structure of the substrate unit 10. For example, the cutting path may be formed by the dielectric layer without forming a circuit layer.

Furthermore, the peripheral area B is connected to the main area A and is positioned outside of the main area A, so that the peripheral area B is removed in the subsequent singulation process.

The peripheral area B is provided with at least one set of inspection pads 12 (including two inspection pads 12). In one embodiment, there are a plurality of sets of inspection pads 12. The distance between two inspection pads 12 in each set can be equal or different, in order to meet the requirements of electrical connection pads 11 with the same or different specifications in the same substrate unit 10. In addition, the material of the inspection pad 12 can be the same as the material of the electrical connection pad 11 (e.g., metal copper), and can be manufactured in the same process.

Referring to FIG. 2B at the same time, the distance between two adjacent inspection pads 12 is Y, and the distance Y between two adjacent inspection pads 12 is less than the distance X between two adjacent electrical connection pads.

Moreover, in order to prevent the electrical connection pad 11 from being oxidized and to improve the bonding force between the electrical connection pad 11 and the electronic component (i.e., semiconductor chip) by, for example, connecting the electronic component and the electrical connection pad via gold wires or solder balls, a surface treatment layer 13, such as a nickel/gold layer is further formed on the outer surface of the electrical connection pad 11.

The surface treatment layer 13 can be formed by electroplating lines (or process) or electroless plating lines (or process), and the surface treatment layer 13 simultaneously forms the outer surfaces of the electrical connection pad 11 and the inspection pad 12.

In one embodiment, the distance X between two adjacent electrical connection pads 11 is 40 μm, and the distance Y between two adjacent inspection pads 12 is 30 μm, the thickness of the surface treatment layer 13 predetermined to be formed on the electrical connection pad 11 is 15 μm.

In situation 1, referring to FIG. 2A and FIG. 2B, if the thickness of the surface treatment layer 13 actually formed on the electrical connection pad 11 is ≥15 μm (the actual thickness of the surface treatment layer 13 may be greater than the predetermined thickness, as long as bridging of the two adjacent electrical connection pads 11 is prevented), that is, the thickness the surface treatment layer 13 formed on the two adjacent electrical connection pads 11 may still be separated by about 10 μm. In this case, since the thickness of the surface treatment layer 13 formed on the two adjacent inspection pads 12 is also ≥15 μm, and the distance Y between the two adjacent inspection pads 12 is only 30 μm (less than the distance X between the two adjacent electrical connection pads, which is 40 μm). Therefore, the surface treatment layer 13 formed on the adjacent inspection pads 12 are in contact with each other.

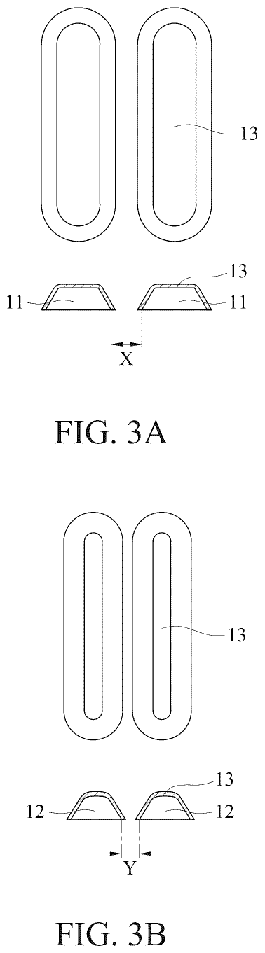

In situation 2, referring to FIG. 3A and FIG. 3B, if the thickness of the surface treatment layer 13 actually formed on the electrical connection pad 11 is <15 μm (the actual thickness of the surface treatment layer 13 does not reach the predetermined thickness). In this case, since the thickness of the surface treatment layer 13 formed on the two adjacent inspection pads 12 is also <15 μm, there are still gaps between the surface treatment layer 13 formed on the adjacent inspection pads 12, and they are not in contact with each other.

Accordingly, by observing whether the surface treatment layer 13 on the two adjacent inspection pads 12 in the peripheral area B of the carrier structure 1 are in contact with each other or leaving a gap, it can be directly determined whether the thickness of the surface treatment layer 13 formed on the electrical connection pads 11 of the substrate unit 10 in the main area A of the carrier structure 1 reaches the predetermined value.

Hence, the carrier structure of the present disclosure is mainly provided with at least two inspection pads in the peripheral area, and the distance between the two inspection pads is less than the distance between the two electrical connection pads disposed in the main area. As such, when a surface treatment layer is formed on the electrical connection pads and the inspection pads, whether the surface treatment layer formed on the electrical connection pads has reached the target thickness can be directly determined by direct vision or microscopic observation of the mutual distance and contact status of the surface treatment layer formed on the two inspection pads. This eliminates the need for destructive test, so as to save manpower, material resources and time costs. Additionally, the carrier structure of the present disclosure can be manufactured with existing semiconductor packaging equipment without developing or purchasing special equipment, thereby reducing production costs and having high technical implementation feasibility.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A carrier structure defined with a main area and a peripheral area adjacent to the main area, the carrier structure comprising:
a plurality of substrate units disposed in the main area, and a plurality of electrical connection pads formed on each of the plurality of substrate units; and
at least two inspection pads disposed in the peripheral area, wherein a distance between the at least two inspection pads is less than a distance between any two of the plurality of electrical connection pads.

2. The carrier structure of claim 1, further comprising a surface treatment layer formed on the plurality of electrical connection pads and the at least two inspection pads.

3. The carrier structure of claim 2, wherein the surface treatment layer is a nickel/gold layer.

4. The carrier structure of claim 1, wherein the carrier structure is in a full-panel or a strip form, and the plurality of substrate units are arranged in an array.

5. The carrier structure of claim 1, wherein the substrate unit provides for an electronic component to be disposed thereon and for the electronic component to be electrically connected to the plurality of electrical connection pads.

6. The carrier structure of claim 5, wherein a cutting path for a singulation process is formed between each of the substrate units.

7. The carrier structure of claim 1, wherein the peripheral area is connected to the main area and is positioned outside the main area.

8. The carrier structure of claim 1, wherein the inspection pads are made of the same material as the electrical connection pads.

9. The carrier structure of claim 1, wherein a plurality of sets of inspection pads are disposed in the peripheral area, each set of inspection pads comprises two of the inspection pads, and a distance between two of the inspection pads in each set is equal.

10. The calibration system of claim 1, wherein a plurality of sets of inspection pads are disposed in the peripheral area, each set of inspection pads comprises two of the inspection pads, and a distance between two of the inspection pads in each set is different.
